(19) United States
(12) Patent Application Publication
(10) Pub. No.: US 2015/0261099 A1
(43) Pub. Date: Sep. 17, 2015

(54) LITHOGRAPHY APPARATUS, AND METHOD OF MANUFACTURING ARTICLE

(71) Applicant: CANON KABUSHIKI KAISHA, Tokyo (JP)

(72) Inventor: Toshiro Yamanaka, Yokohama-shi (JP)

(21) Appl. No.: 14/637,995

(22) Filed: Mar. 4, 2015

(30) Foreign Application Priority Data
Mar. 14, 2014 (JP) 2014-052428

(51) Int. Cl. G03F 7/20

(52) U.S. Cl. CPC G03F 7/70141

(57) ABSTRACT

A lithography apparatus advantageous in increasing both a throughput and overlay accuracy is provided. The apparatus includes a plurality of charged particle optical systems each irradiating a substrate with a charged particle beam, and a plurality of alignment sensors including an alignment sensor located among the plurality of charged particle optical systems. A processor generates, in parallel with a patterning, information on at least one of a position and a shape of a region on the substrate based on outputs from the plurality of alignment sensors.

### BACKGROUND OF THE INVENTION

1. Field of the Invention

The present invention relates to a lithography apparatus, and a method of manufacturing an article.

2. Description of the Related Art

In the manufacture of a semiconductor device, the need for refining the line width is becoming stricter year by year. One of production apparatuses which obtains a resolution with a line width of 10 nm or less is an electron beam lithography apparatus. In particular, a multi-electron beam lithography apparatus which writes patterns simultaneously with a plurality of electron beams without using any mask has been proposed (Japanese Patent Laid-Open No. 2011-513905). The multi-electron beam lithography apparatus has many advantages, toward practical applications, that it eliminates the need for a mask which is one factor of manufacturing cost, and it can control respective electron beams in a programmable manner, and is thus suitable for manufacturing a variety of devices in small quantities, and the like.

It is possible to change a target value for a writing position by shifting writing pattern data and correct a positional shift in writing (see Japanese Patent No. 3940310). Alternatively, it is also possible to change the target value for the writing position by a scanning deflector.

In general, however, electron beam lithography takes writing time about ten times or more for the same field size as compared to optical lithography and thus has poor throughput. On the other hand, if the number of beams that can perform writing at the same time is increased making much account of the high throughput, it becomes difficult to make uniform the electron-optical characteristic of the beams, thus reducing the resolution. Furthermore, if the total number of electron beams which irradiates a wafer increases, the wafer has the temperature distribution and fluctuation, and the overlay accuracy decreases by the distribution and the fluctuation of a wafer deformation caused by the temperature distribution and fluctuation of the wafer.

### SUMMARY OF THE INVENTION

The present invention provides, for example, a lithography apparatus advantageous in both a throughput and overlay accuracy thereof.

According to one aspect of the present invention, a lithography apparatus which performs patterning on a substrate with a charged particle beam is provided. The apparatus includes a plurality of charged particle optical systems each configured to irradiate the substrate with a charged particle beam, a plurality of alignment sensors including an alignment sensor located among the plurality of charged particle optical systems, and a processor configured to generate, in parallel with the patterning, information on at least one of a position and a shape of a region on the substrate based on outputs from the plurality of alignment sensors.

Further features of the present invention will become apparent from the following description of exemplary embodiments (with reference to the attached drawings).

### BRIEF DESCRIPTION OF THE DRAWINGS

FIG. 1 is a view showing an example of the basic arrangement of a multi-electron beam lithography apparatus;

FIG. 2 is a schematic view for explaining an example of the layout of an alignment sensor array according to an embodiment;

FIG. 3 is a schematic view for explaining an example of the layout of an alignment sensor array according to an embodiment;

FIG. 4 is a flowchart showing an exposure control procedure according to the embodiment;

FIG. 5 is a view showing an example of the calculation of the temperature fluctuation and distribution of a wafer;

FIG. 6 is a view showing an example of the calculation of a wafer deformation fluctuation in an x direction within writing areas;

FIG. 7 is a view showing an example of the calculation of the wafer deformation fluctuation in a y direction within the writing areas;

FIG. 8 is a view showing an example of the calculation of writing errors in the x direction within the writing areas;

FIG. 9 is a view showing an example of the calculation of the writing errors in the y direction within the writing areas;

FIG. 10 is a view showing an example of the arrangement of a multi-electron beam lithography apparatus according to an embodiment;

FIG. 11 is a view showing an example of the arrangement of a wafer stage;

FIG. 12 is a schematic view for explaining an example of the layout of an alignment sensor array according to another embodiment; and

FIG. 13 is a schematic view for explaining an example of the layout of the alignment sensor array according to the other embodiment.

### DESCRIPTION OF THE EMBODIMENTS

Various exemplary embodiments, features, and aspects of the invention will be described in detail below with reference to the drawings.

Preferred embodiments of the present invention will be described in detail below with reference to the accompanying drawings. Note that the following embodiments are not intended to limit the present invention and are merely concrete examples advantageous in practicing the invention. Also, not all combinations of features to be described in the embodiments are indispensable for the means to solve the problems according to the present invention. Note that the same reference numerals denote the same members throughout the drawings, and a repetitive description thereof will not be given.

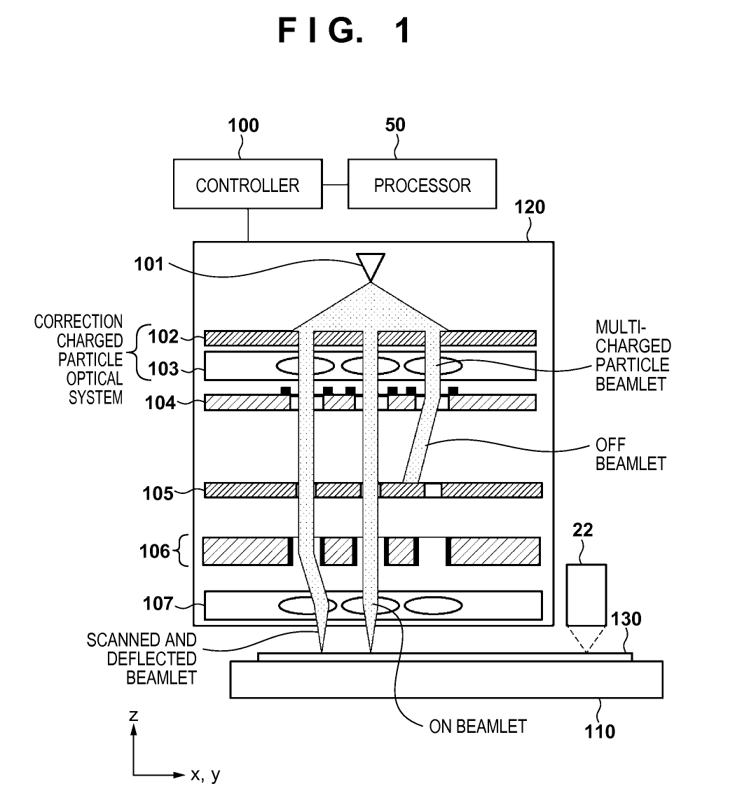

FIG. 1 shows an example of the arrangement of a multi-electron beam lithography apparatus. The multi-electron beam lithography apparatus includes a wafer stage 110 which holds and positions a wafer 130 serving as a substrate on which pattern formation is performed, and a charged particle optical system 120.

The charged particle optical system 120 generally has the following arrangement. That is, a charged particle source 101 generates electron beams. A multi-aperture array 102 divides the electron beams into a plurality of arrays. Each collimator lens 103 sets the electron beam at an appropriate angle. The multi-aperture array 102 and the collimator lenses 103 compose a correction charged particle optical system. A blanking deflector array 104 performs ON/OFF control of multi-electron beams. A beam stop aperture array 105 cuts off the OFF-controlled multi-electron beam. A scanning deflector 106 deflects the ON-controlled multi-electron beams. A projection optical system 107 demagnifies the ON-controlled multi-electron beams.

A controller 100 is composed of a computer including a CPU and a memory, and controls the entire apparatus according to a program stored in the memory. The controller 100 controls writing processes for forming a pattern on the wafer by controlling the operation of each unit described above.

The lithography apparatus according to this embodiment has an arrangement in which the charged particle optical systems 120 as described above are located in an array (details of which will be described later). That is, this embodiment includes the plurality of charged particle optical systems each of which irradiates the substrate with charged particle beams. The lithography apparatus according to this embodiment also includes an alignment sensor array including a plurality of alignment sensors 22 configured to perform alignment measurement on the surface of the wafer 130. A processor 50 generates information on at least one of a position and a shape of a region on the substrate based on outputs from the plurality of alignment sensors. This makes it possible to detect a wafer deformation by detecting a feature part (for example, an alignment mark). The processor 50 can also generate, based on the above-described information, control data for controlling the positions of at least one among the wafer and the charged particle beams. The controller 100 controls the incident position of the charged particle beam with respect to the wafer to cope with this wafer deformation. More specifically, for example, the controller 100 corrects data in a writing target position with respect to the wafer based on the detected deformation.

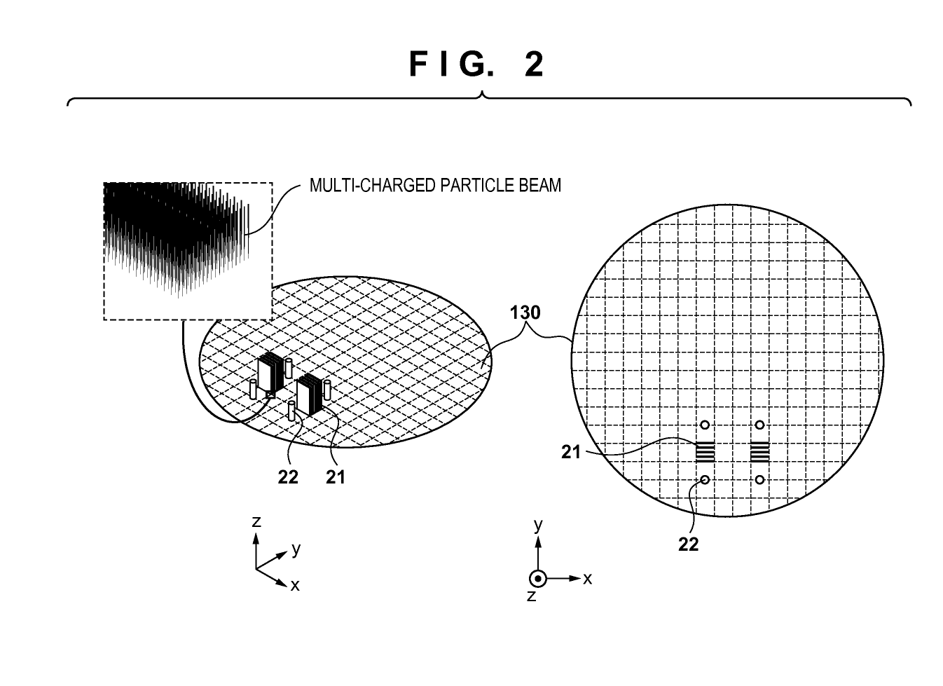

FIG. 2 is a schematic view for explaining an example of the layout of the alignment sensor array according to this embodiment. As shown in FIG. 2, a writing area array is set as two or more writing areas 21 apart from each other in a direction within an x-y plane. As shown in an enlarged view in FIG. 2, each writing area has an optical axis in a −z direction and includes a number of multi-charged particle beams located in an array in the direction within the x-y plane. The alignment sensor array includes the plurality of alignment sensors 22 located in positions adjacent to the writing areas 21 within the x-y plane. The relative x-y position between each multi-beam optical axis and the alignment sensor array is fixed. It is possible, however, for a deflector (not shown) to slightly displace each multi-beam from each optical axis. Furthermore, the wafer 130 can be moved by a wafer moving mechanism (not shown) over a long distance in the direction within the x-y plane, and change its relative position against each multi-beam and the alignment sensor array. With this arrangement, processing of writing an appropriate pattern in a certain partial region on the wafer 130, and then moving the wafer 130 to write a pattern in another partial region is repeated by the writing area array.

As described above, such a writing step takes relatively a long time, thus tending to cause the deformation of the wafer 130. It is possible, however, to detect the deformation on the wafer surface around each writing area by the alignment sensor array, and maintain high overlay accuracy by correcting each multi-beam position or wafer position based on this detected value.

Note that it is possible to form an alignment mark in advance in a position to fall within the angle of view of each alignment sensor 22 if the x-y trajectory of the wafer 130 during the writing step is determined in advance. This makes it possible to perform an alignment measurement step in parallel with the writing step and reduce a decrease in a throughput caused by the alignment measurement step to almost zero. Alignment measurement can be finished within the time required for writing a certain area. Since the writing time is relatively long, it is possible to ensure a time for maintaining high alignment measurement accuracy.

If it is impossible to detect the alignment mark during the writing step, the alignment measurement step may be performed by temporarily interrupting the writing step and moving the wafer 130 to the alignment mark position to fall within the angle of view of each alignment sensor. Even in this case, the range of wafer movement is just about the size of each writing area at maximum. So the time required for the movement can be minimum. Therefore, this arrangement acts advantageously.

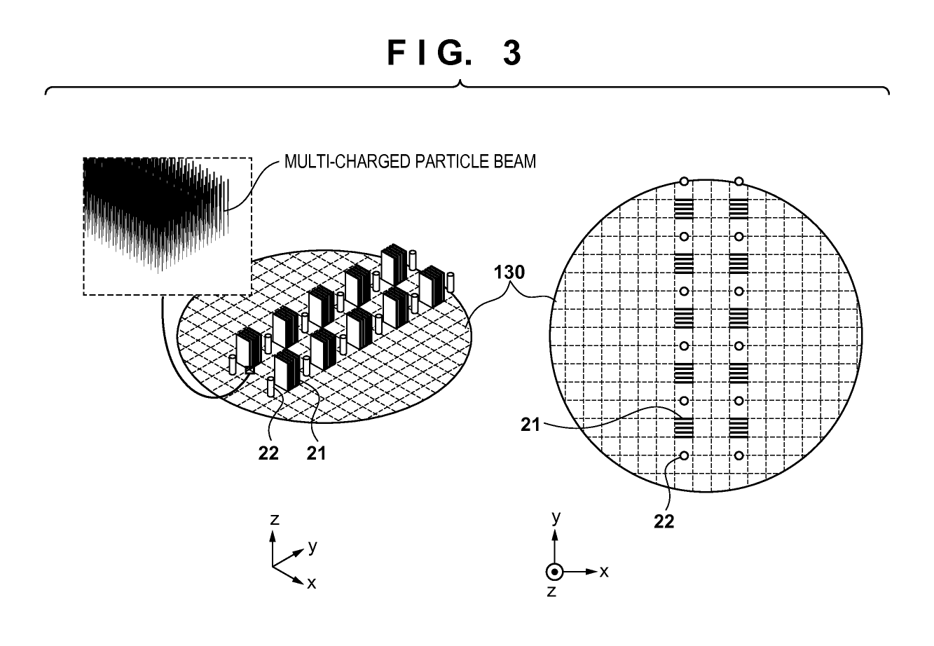

FIG. 3 is a schematic view for explaining an example of the layout of an alignment sensor array according to another embodiment. As shown in FIG. 3, a plurality of writing areas are located in a y direction. Furthermore, at least one alignment sensor 22 is located between the adjacent writing areas in the y direction. In this case, it is desirable for the wafer 130 to continuously move along the x-y trajectory mainly in the y direction.

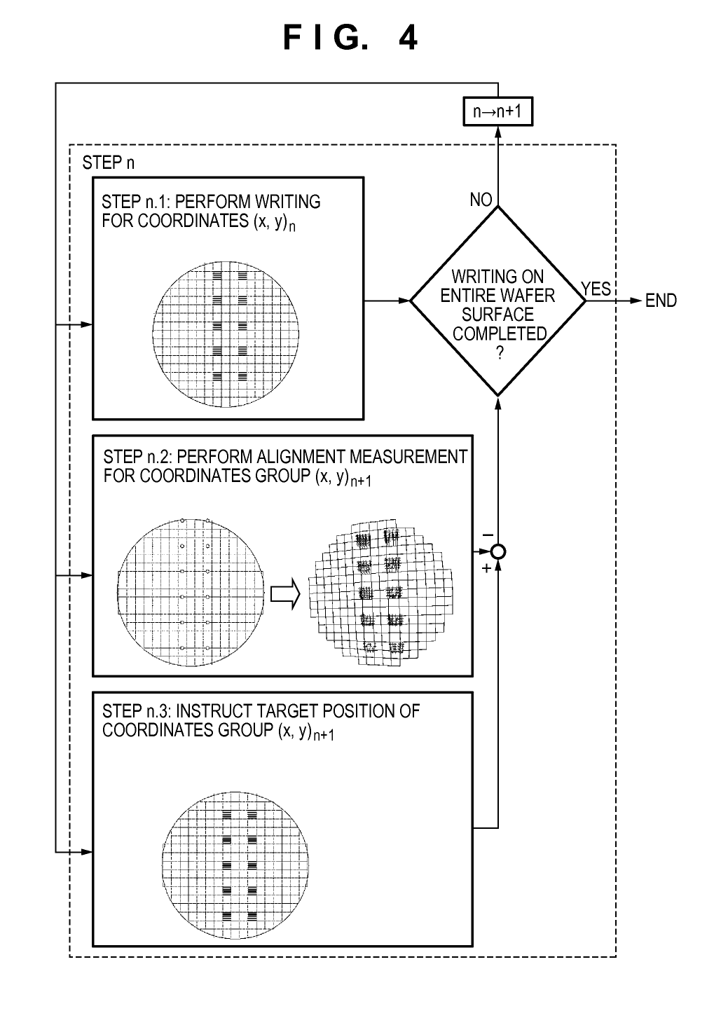

FIG. 4 is a flowchart showing an exposure control procedure for one wafer according to the embodiment. Reference symbol n indicates an exposure step number for one wafer.

In step n.1, writing is performed for a coordinates group (about first region) which is composed of the target coordinates of each multi-beam as shown below:

$${( x , y )}_{n} = {[ \begin{matrix}{x}_{1} & {y}_{1} \\ {x}_{2} & {y}_{2} \\ ⋮ & ⋮\end{matrix} ]}_{n}$$

On the other hand, in step n.2, alignment measurement is performed for a coordinates group (x, Y)ₙ₊₁ (about second region) serving as a next writing target positions. These alignment measurement results represent wafer deformations at the positions of the coordinates group (x, y)ₙ₊₁ when step n was performed.

Furthermore, in step n.3, a specific writing target positions with respect to the coordinates group (x, y)ₙ₊₁ are commanded. Data obtained by subtracting the alignment measurement results from these target positions are used as writing target positions in next step n+1. By doing so, correction of data in writing target positions related to writing in the second region is performed.

The above steps are repeated until the entire wafer surface undergoes writing. Note that steps n.1, n.2, and n.3 can be processed in parallel within the time of one step. It is therefore possible to write a desirable pattern on the entire wafer surface without being influenced by the spatial distribution and the time variation of the wafer position.

(Numerical Example)

A numerical example showing the arrangement in FIG. 3 and the effect of steps in FIG. 4 will be shown below. Assuming that a wafer has the diameter of 450 [mm], the physical properties of single crystal Si are used for the wafer and the physical properties of SiC are used for a wafer stage. It is assumed that the speed of the writing and the stage is 13 [mm/sec], the size of each writing area is 26 mm×26 mm, the number of writing areas is 10, and the heat flux to each writing area is 300 [W/m2]. Also it is assumed that the wafer stage is stabilized at a uniform temperature. In this case, the total number of shots “221” requires about 66 [sec] per one wafer. Therefore, a throughput of about 55 wafers per hour (55 wph) is obtained for the wafer of φ450 mm. This value is almost equal to that of a conventional optical lithography apparatus.

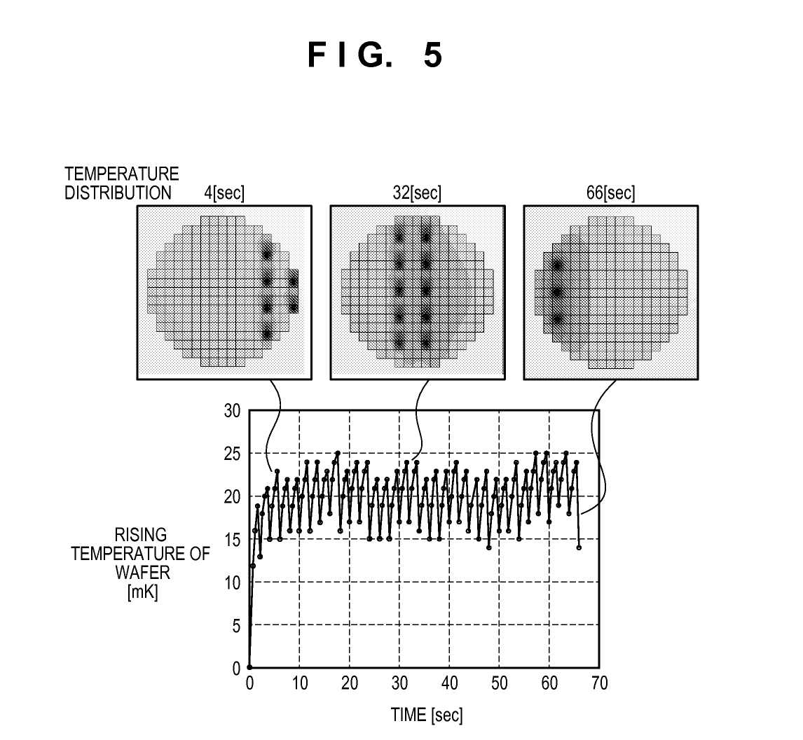

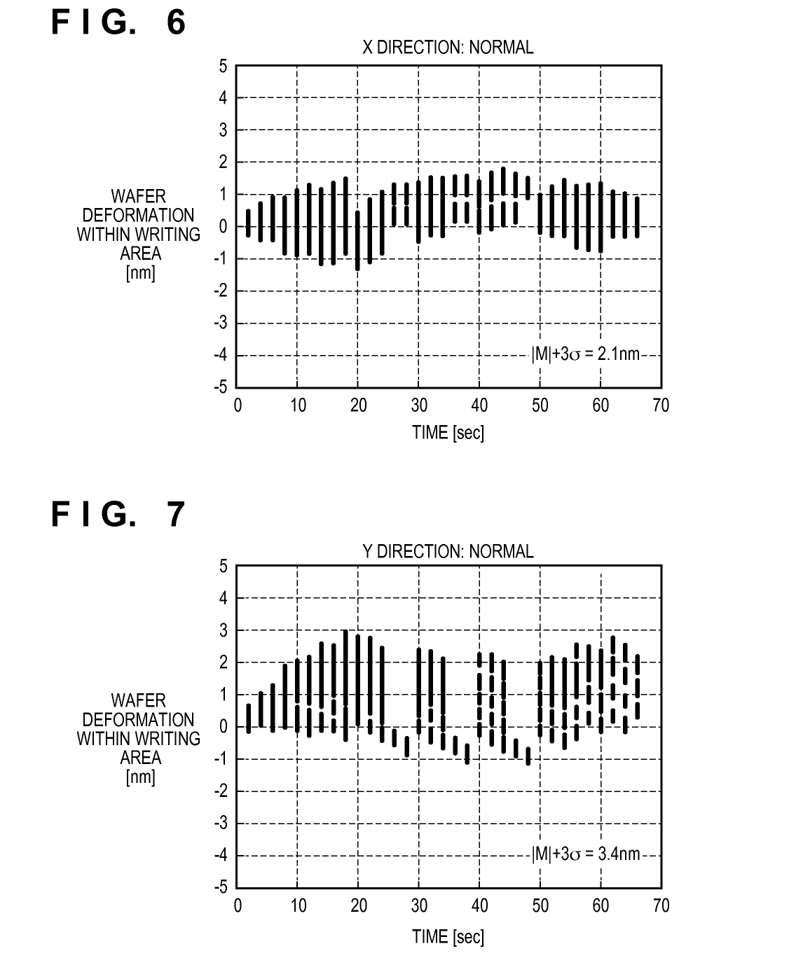

FIG. 5 shows a result of a transient thermal conductivity analysis by an FEM (Finite Element Method) in this case. While performing writing for one wafer, the temperature distribution of the wafer varies depending on time in the range of about 0 to 25 [mK]. Also, the temperature distribution at each time changes depending on writing positions. FIGS. 6 and 7 show the result of the thermal stress deformation analysis in each writing area caused by the temperature fluctuation. FIGS. 6 and 7 show the deformations in an x direction and a y direction, respectively. As shown in FIGS. 6 and 7, the spatial distribution and the fluctuation of the deformations within each writing area occur complexly depending on time and the writing positions. Numerically, for |M|+3σ,

x direction: 2.1 [nm], y direction: 3.4 [nm] are obtained. Even if an overlay measurement step is performed before a wafer exposure step as in a conventional optical lithography apparatus, the above-described error cannot be detected because of the difference in temperature conditions between the overlay measurement step and the wafer exposure step. As a consequence, the above-described error becomes a writing error directly. Recently, a requirement from a market for the overlay accuracy of a high resolution lithography apparatus is generally at least 5 [nm] or less, so the above-described errors are regarded as sufficiently large values.

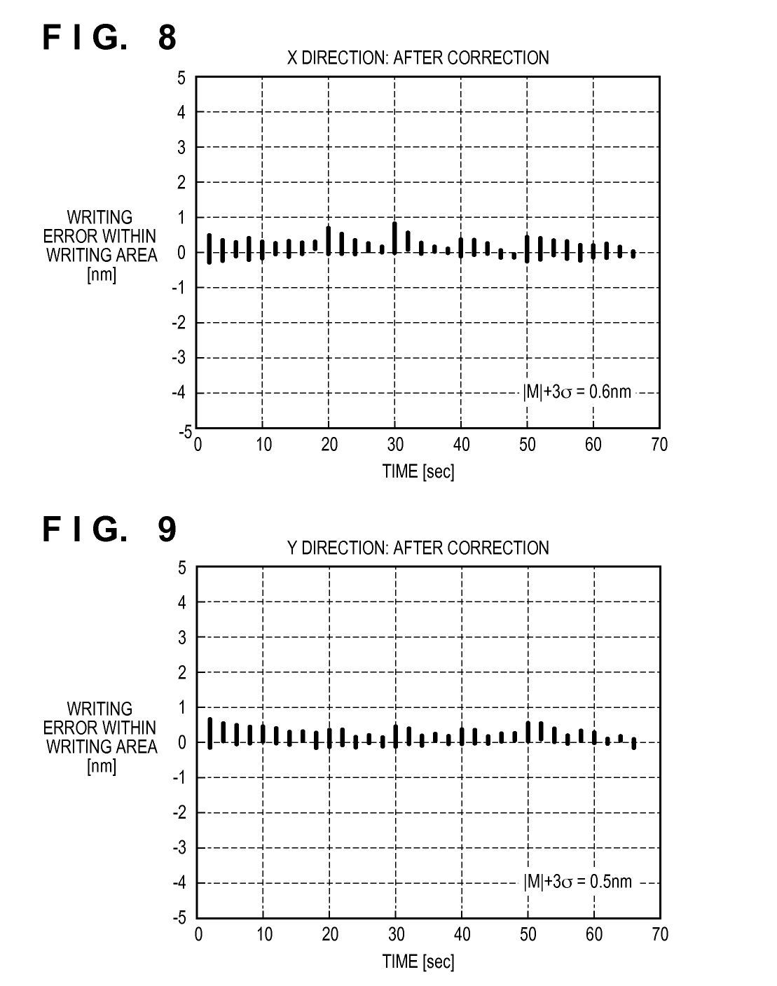

On the other hand, according to the arrangement and the steps of this embodiment, it is possible to measure and correct the deformation amount in a next step. FIGS. 8 and 9 show the writing errors in this case. FIGS. 8 and 9 show the deformations in the x direction and the y direction, respectively. As shown in FIGS. 8 and 9, for |M|+3σ,

x direction: 0.6 [nm], y direction: 0.5 [nm] are obtained and they can be equal to or less than sub nm. A time required for one step which is assumed by calculation is 2 [sec], and the period of measurement and correction should be within 2 [sec]. This condition for the period can sufficiently be implemented.

Furthermore, correction may be performed using a prediction model and a physical model which considers the difference in times required for one step, and the difference between the writing positions and heat input positions. Correction may also be performed using the prediction model which depends on at least one among the writing positions and the heat input amount. In these cases, it is possible to further reduce the above-described errors.

However, the above-described calculation example is given for confirming an effect, and the present invention is not limited to the shape and the size of a certain writing area. The shape of the writing area may be, for example, a rectangle, a polygon, or a circle. The present invention is also applicable to a case in which a plurality of sub writing areas are also formed within one writing area. The number of writing areas is not limited either. It is desirable, however, to change it to an appropriate number depending on the diameter of the wafer.

Furthermore, the present invention is effective for the factors of the wafer deformation such as not only a heat input but also another fluctuation factor. The wafer deformation can occur, for example, depending on another stress or by the stick-slip between the wafer and a wafer chuck. As compared to a conventional technique, the present invention is more effective for such an irreversible or probabilistic fluctuation.

### Example

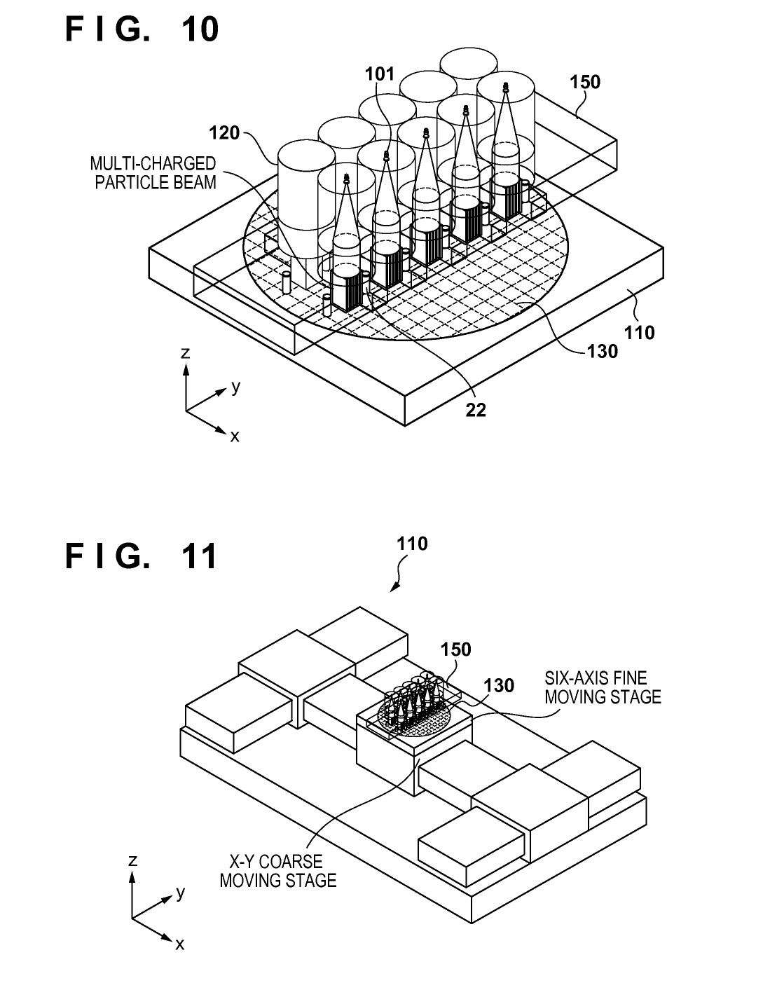

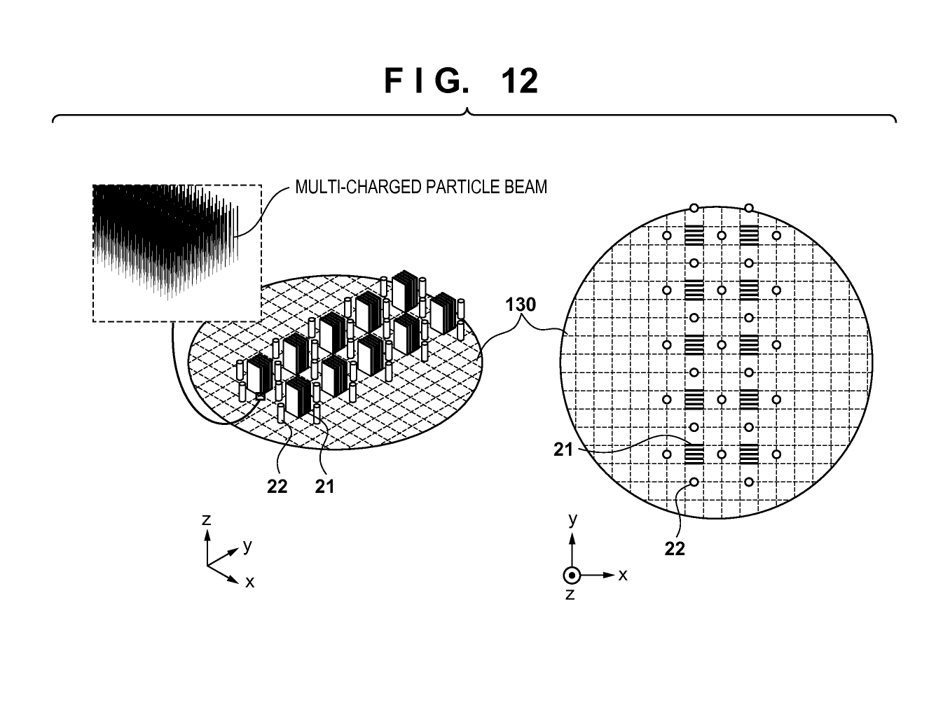

A detailed example will be described with reference to FIGS. 10 and 11. FIG. 10 shows an example of an arrangement for implementing FIG. 3. In this example, a plurality of charged particle optical systems 120 each corresponding to a writing area are configured, and a support structure 150 supports charged particle optical system arrays and alignment sensor arrays. It is desirable for the support structure 150 to stabilize the relative position between respective supported objects, and thus to have zero expansion materials or a combination thereof, or a structure which undergoes appropriate temperature control.

At least one of the alignment sensor arrays is located between at least two of the plurality of charged particle optical systems. As a result, as shown in FIG. 3, each alignment sensor is located between the writing areas.

Each charged particle optical system includes the charged particle optical elements shown in FIG. 1. Therefore, each writing area includes a charged particle source 101. Each writing area is assumed to have the size of several 10 [mm]. In this case, each collimator lens which makes charged particle beams parallel needs to have an outer shape which is twice or more as large as the writing area in size. As described above, considering the fact that there is a restriction on the size of the collimator lens, it is appropriate to separate the writing areas from each other. Each charged particle optical system 120 is assumed to have the height of several 100 [mm].

A wafer stage 110 can hold and move a wafer 130. As shown in FIG. 11, it is desirable that the wafer stage 110 is configured with a six-axis fine moving stage which finely adjusts the rigid position of the wafer 130 and an x-y coarse moving stage which moves by a long stroke about the same size as the wafer.

### OTHER EMBODIMENTS

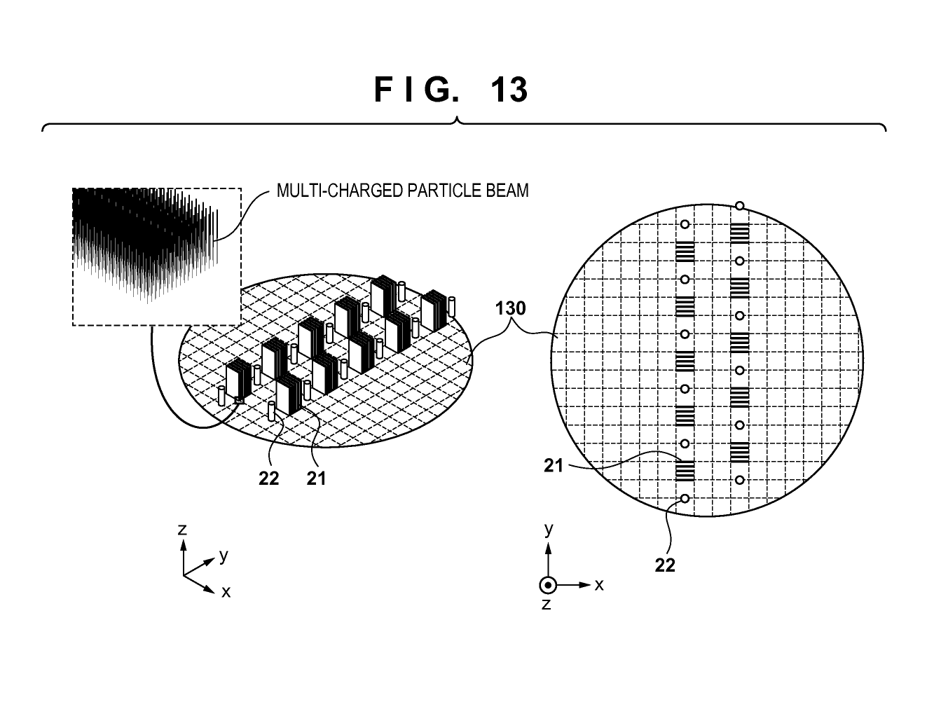

As another example, a plurality of alignment sensors may be located in the outer peripheral portions of a plurality of charged particle optical systems. As a result, as shown in FIG. 12, the alignment sensors are located in the outer periphery of a writing area array and intermediate positions in an x direction. Furthermore, as shown in FIG. 13, y-direction arrays whose x positions are different from each other may be located in positions which are different from each other in the y direction.

### Embodiment of Method of Article Manufacturing

A method of manufacturing an article according to an embodiment of the present invention is suitable for manufacturing the article, for example, a microdevice such as a semiconductor device or an element having a microstructure. The method of manufacturing the article according to this embodiment includes a step of forming a latent image pattern on a photoresist applied to a substrate using the above-described lithography apparatus (step of performing writing on the substrate), and a step of developing the substrate on which the latent image pattern has been formed in the preceding step. This manufacturing method further includes other known steps (oxidation, deposition, vapor deposition, doping, planarization, etching, resist peeling, dicing, bonding, packaging, and the like). The method of manufacturing the article according to this embodiment is advantageous in at least one of the performance, the quality, the productivity, and the production cost of the article, as compared to a conventional method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-052428, filed Mar. 14, 2014, which is hereby incorporated by reference herein in its entirety.

What is claimed is:

1. A lithography apparatus which performs patterning on a substrate with a charged particle beam, the apparatus comprising:
a plurality of charged particle optical systems each configured to irradiate the substrate with a charged particle beam;
a plurality of alignment sensors including an alignment sensor located among the plurality of charged particle optical systems; and
a processor configured to generate, in parallel with the patterning, information on at least one of a position and a shape of a region on the substrate based on outputs from the plurality of alignment sensors.

2. The apparatus according to claim 1, wherein the processor is configured to generate, based on the information, control data for controlling a position of at least one of the substrate and the charged particle beam.

3. The apparatus according to claim 2, wherein the processor is configured to perform in parallel
control of the patterning via the plurality of charged particle optical systems with respect to a first region on the substrate, and
generation of the information via the plurality of alignment sensors with respect to a second region on the substrate.

4. The apparatus according to claim 2, wherein said processor is configured to generate the control data based on a prediction model, which depends on data for the patterning and the information.

5. The apparatus according to claim 1, wherein the plurality of alignment sensors include an alignment sensor located at a periphery of the plurality of charged particle optical systems.

6. A method of manufacturing an article, the method comprising steps of:
performing patterning on a substrate using a lithography apparatus; and
processing the substrate, on which the patterning has been performed, to manufacture the article,
wherein the lithography apparatus includes:
a plurality of charged particle optical systems each configured to irradiate the substrate with a charged particle beam;
a plurality of alignment sensors including an alignment sensor located among the plurality of charged particle optical systems; and
a processor configured to generate, in parallel with the patterning, information on at least one of a position and a shape of a region on the substrate based on outputs from the plurality of alignment sensors.
